(19) United States
(12) Patent Application Publication
(10) Pub. No.: US 2006/0014309 A1
(43) Pub. Date: Jan. 19, 2006

(54) Temporary chip attach method using reworkable conductive adhesive interconnections

(76) Inventors: Krishna Gandhi Sachdev, Hopewell Junction, NY (US); Daniel George Berger, New Paltz, NY (US); Kelly May Chioujones, San Diego, CA (US); Richard F. Indyk, Wappingers Falls, NY (US)

Correspondence Address: lBM Corporation;Intellectual Property Law, Building 300-482, Dept. 18G, 2070 Route 52, Hopewell Junction, NY, 12533, US

(21) Appl. No.: 10/891,542

(22) Filed: Jul. 13, 2004

(51) Int. Cl. G01R 31/26; H01L 21/66

(52) U.S. Cl. 438/17

(57) ABSTRACT

A method for temporary chip attach to determine known good die using a reworkable conductive adhesive interconnection between the chip carrier and die. The die is easily separated from the chip carrier after test, without the use of potentially damaging shear forces, by subjecting the TCA assembly to a rework solution.

### RELATED APPLICATIONS

This application is related to subject matter described and claimed in U.S. patent application Ser. No. 10/709,518 (attorney docket no. FIS9-2003-0420US1) entitled “Thermal Interface Adhesive and Rework” by the inventors of the instant application.

### BACKGROUND OF THE INVENTION

1. Field of the Invention

The present invention relates to reworkable conductive adhesive compositions having high electrical conductivity for temporary chip connections and bum-in, for the purpose of testing the performance of semiconductor devices prior to final assembly on a chip carrier. More particularly, this invention is concerned with the use of conductive adhesives with improved properties in terms of electrical conductivity, thermal stability, compatibility with component interfacing metallurgy and having the special feature of reworkability which allows semiconductor device or die removal from the chip carrier substrate by exposure to a suitable rework solution without the need to apply shear force to remove the semiconductor device.

In the case of ceramic chip carriers, particularly the high density high performance glass ceramic chip carriers with copper via metallurgy, the method according to the present invention has the distinct advantage of providing a temporary chip attachment (TCA) method for semiconductor device pre-screening that does not depend on selective solder wetting. It does not require any special test vehicle design with multiple layer metallurgy schemes and therefore minimizes or eliminates the chance of semiconductor device or die damage that can occur with the die shear method.

2. Description of Related Art

With rapid advancements in the design and fabrication of high performance multichip electronic modules (MCM), and increasing focus on miniaturization and higher speed operations for commercial and consumer products requiring the use of complex circuitry device chips, it is important to have a simple and efficient method for Known Good Die (KGD) testing prior to assembly to eliminate/reduce product yield loss and thereby reduce production cost and assure long term reliability of device performance. Various methods for pre-screening die for wire bond and solder ball flip-chip interconnections (C4) are based on temporary packaging of the chip employing metallurgical connections and testing through burn-in and then the chip is sheared off of the carrier. This method involves multiple processing steps and the chip removal from the temporary package generally requires shear force which itself can cause detriment to the chip function.

A TCA method which has found application for ceramic electronic modules, specifically, alumina ceramic chip carrier where the via and wiring metallurgy is molybdenum, is based on selective surface metallization which involves forming nickel bumps of smaller diameter on top of the Mo via to form a donut type structure followed by a standard flip-chip joining process where the selectivity in solder wetting of Ni and non-wetting of Mo allows reduced area interconnections to be made. The flip-chip assembly is then subjected to test and burn-in to determine the functional performance and reliability of the silicon device which is then removed by the shearing method requiring a lower shear force due to reduced area contact C4 connections.

However, the applicability of this approach has been limited to alumina ceramic with Mo metal vias only and is not extendable to performing TCA based on reduced area contact joining to lower the die shear force in the case of high performance glass ceramic electronic modules with copper via metallurgy. This is because there is no significant difference in the Pb/Sn solder wettability of Ni and the underlying Cu via coupled with the fact that glass ceramic is much more fragile and the advanced technology silicon devices have highly dense, complex circuit design, and smaller size with closely spaced features, and narrow pitch C4 arrays. This increases the possibility for damage to the chip and/or the TCA carrier under high stress caused by higher shear force required to separate the chip from the temporary carrier.

The ability to remove the die after test and burn-in with a low shear force is necessary to make sure that no damage occurs to complex device circuitry during the process. This requirement has become more critical with the use of low k and ultra low k dielectrics in advanced/future electronic products. Several methods for temporary chip attachment (TCA) have been described in the prior art with particular attention being drawn to the method based on selective metal solder wetting as it applies to alumina ceramic chip carriers with Mo via metallurgy. Still other methods utilize low melting solder alloys or reduced solder contact area by using high grit-filled metal vias to limit the conductive via phase contact area.

U.S. Pat. No. 6,221,682 (Danziger, et al.,) the disclosure of which is incorporated by reference herein, is concerned with a method for known good device testing using metallurgical connections with both wire bond and flip-chip interconnects where solder ball array connection (C4) and wire bond pads are combined on a planar surface of an IC device. The KGD testing is done using solder ball or wire bond pads prior to final use, with the wire bond pads used for test, leaving the solder ball or C4 array contacts unaffected for bonding final end product device.

U.S. Pat. No. 6,365,977 (Edwards, et al.), the disclosure of which is incorporated by reference herein, is concerned with a structure and a method for known good die (KGD) which teaches the use of a substrate having solder wettable pads where the cross-sectional area of the pads is reduced by assembling a thin, effectively non-conductive interposer, such as a polyimide film, with smaller diameter holes. The flip chip solder connections are formed by reflow as the solder passes through the interposer holes. The reduced cross-sectional area of the solder connection causes reduction in bond strength and thus, after burn-in and test, the chip can be safely sheared off of the substrate without damaging the die.

U.S. Pat. No. 6,303,400 (Interrante, et al.), the disclosure of which is incorporated by reference herein, is concerned with the temporary attachment of semiconductor devices to substrates using different fusible materials for each component such that the first fusible material on the first component or the device is a lead/tin alloy and the second component has a second fusible material which can also have a via or a via and a pad. The fusible material can be tin, indium, lead/tin alloy, and the first group has a higher melting point than the second group of fusible material. Because of the difference in the melting point of the two fusible materials, the components can be joined without melting the first volume of the fusible material which allows the electrical testing and burn-in on the semiconductor device which is then separated from the substrate by cold shear, hot shear or hot tensile pull.

U.S. Pat. No. 6,376,054 (Langenthal, et al.), the disclosure of which is incorporated by reference herein, describes a surface metallization structure for multichip test and burn-in which uses a ceramic TCA carrier produced with high-grit (inorganic filler as glass and alumina) conductive paste filled TSM vias. The conductive material in the screened via is non-solderable, such as molybdenum and tungsten, over which a solder wettable thin conductive pad is formed by nickel plating process. Besides alumina ceramic sintered substrates, this structure is also claimed to be applicable to glass ceramic and copper, silver, silver/palladium alloy, copper/nickel alloy as the conductive paste materials. For die test, the flip-chip connection occurs with the conductive phase in the via and no contact with the inorganic phase portion and thereby providing a weaker bond allowing the die to be removed at a lower shear force after the test and burn-in.

U.S. Pat. No. 6,528,352 (Jackson et al,), the disclosure of which is incorporated by reference herein, is concerned with forming a temporary chip attach carrier using conductive adhesives for electrical connections where a secondary layer comprising one of ceramic and organic materials having a plurality of holes is applied onto a ceramic chip carrier and then filling in the holes with a thermoplastic or thermoset conductive adhesive and curing the adhesive. For performing die test, a chip having C4 solder bumps is placed onto the secondary layer, applying force onto the chip, electrical test and burn-in, and then removing the chip from the TCA carrier and re-using the secondary layer.

U.S. Pat. No. 6,139,661 (Cronin, et al.), the disclosure of which is incorporated by reference herein, describes a two step SMT method for temporarily attaching an electrical component to a pad located on the substrate, removing or replacing it if necessary prior to the final assembly without damaging the substrate or the components mounted thereon. The method utilizes a conductive radiation-curable adhesive layer between the component lead and the pad on a substrate, adhesive applied by stencil printing, exposure to radiation through a mask to cause crosslinking/curing in the selected/limited portions and allowing easy removal of the component from the pad by applying small mechanical force. Attachment of the component is brought about through the remaining/uncured area which is then fully cured by exposing to radiation to provide final assembly.

U.S. Pat. No. 5,237,269 (Aimi et al.), the disclosure of which is incorporated by reference herein, provides a reduced area solderable connection on a substrate by masking the solderable area with an overlay with holes where the overlay material is not wet by solder and thus the C4 solder ball connections are made only with a limited solderable area of the substrate, allowing die removal at a smaller force without damage after test and bum-in.

U.S. Pat. No. 5,488,200 (Tsukada et al.), the disclosure of which is incorporated by reference herein, disclose a method for reusing SCM and MCM substrates by end milling the chips and the underfill off the top surface of the substrate and establishing a planar surface of residual C4 solder to which a new chip is joined using low temperature solder.

Notwithstanding the prior art, and considering the limitations and drawbacks of the existing TCA methods for application to ceramic chip carriers, particularly to high performance glass ceramic chip carriers there remains a need for an improved and practical TCA method, preferably not requiring die shear for removal after test and burn-in, and that it has the advantages of simplicity and efficiency in pre-assessing device performance and reliability.

These and other purposes of the present invention will become more apparent after referring to the following description considered in conjunction with the accompanying drawings.

### BRIEF SUMMARY OF THE INVENTION

A method for temporary chip attach comprising the steps of applying reworkable conductive adhesive bumps of desired dimension and spacing on the contact pads of a TCA chip carrier substrate; partially drying the adhesive bumps; placing and aligning the electrical contacts on a semiconductor chip to be tested with the adhesive bumps on the substrate contact pads to create a conductive interface; applying a force sufficient on the top of the semiconductor chip to keep the semiconductor chip/substrate assembly in alignment and maintaining pressure during the subsequent curing step.

For test and burn-in operations to evaluate the functional performance of the device, a heatsink is placed on the back of device with a cooling medium or thermal interface material interposed between the heatsink and the silicon chip. The assembly is then subjected to test and burn-in according to the temperature/time requirement for a particular device design and desired product performance.

In order to separate the device from the TCA after test and burn-in, the method further comprises exposing the assembly to a rework solution that selectively softens and disrupts the adhesive joint between the contact pads and adhesive bumps; and removing the semiconductor chip from said substrate.

The method further comprises subjecting the removed semiconductor chip and substrate to a rinse cycles with solvent; subjecting the removed semiconductor chip and substrate to a rinse cycle with deionized water; subjecting the removed semiconductor chip and substrate to a rinse cycle with IPA; and drying the semiconductor chip and substrate thereby cleaning the chip and substrate of the adhesive deposits.

In another embodiment there is disclosed a method for temporary chip attach providing multiple use of a TCA chip carrier comprising the steps of applying a first array of non-reworkable conductive adhesive bumps of desired dimension and spacing on the contact pads of a TCA substrate and curing the adhesive bumps; applying a second array of reworkable conductive adhesive bumps on the top of the first cured array; partially drying the second array of reworkable adhesive bumps; placing and aligning a semiconductor chip to be tested such that the electrical contacts, for example, solder ball array connections (C4s), are in contact with the adhesive bumps on the substrate to create a conductive interface; applying sufficient force to the semiconductor chip to keep the semiconductor chip/substrate assembly in alignment and maintaining pressure during the subsequent curing step.

For test and burn-in operations to evaluate the functional performance of the device, a heatsink is placed on the back of device with a cooling medium or thermal interface material interposed between the heatsink and the silicon chip. The assembly is then subjected to test and burn-in according to the temperature/time requirement for a particular device design.

In another aspect of the invention, the reworkable conductive bumps can be formed on the top of the semiconductor device electrical contact array, partially dried, and then assembled with the substrate contact pads. Alternatively, the reworkable adhesive bumps height can adjusted such that the adhesive bumps can be used to replace the solder ball ball array on the semiconductor device.

The method further comprises exposing the assembly to a rework solution that selectively softens and disrupts the second array of adhesive bumps; and removing the semiconductor chip from the substrate.

The method further comprises subjecting the removed semiconductor chip and substrate to a rinse cycles with solvent; subjecting the removed semiconductor chip and substrate to a rinse cycle with deionized water, subjecting the removed semiconductor chip and substrate to a rinse cycle with IPA; and drying the semiconductor chip and substrate thereby cleaning the chip and substrate of the second array of adhesive bumps.

### BRIEF DESCRIPTION OF THE DRAWIGS

The features of the invention believed to be novel and the elements characteristic of the invention are set forth with particularity in the appended claims. The Figures are for illustration purposes only and are not drawn to scale. The invention itself, however, both as to organization and method of operation, may best be understood by reference to the detailed description which follows taken in conjunction with the accompanying drawings in which:

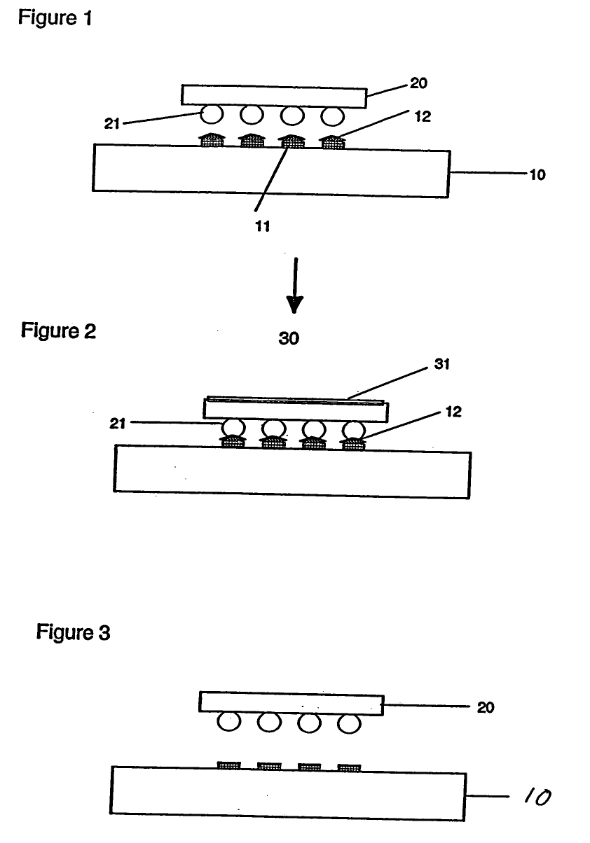

FIG. 1 shows a representative sintered ceramic single chip carrier substrate.

FIG. 2 shows the assembled structure 30 after the flip-chip placement.

FIG. 3 shows the separated TCA carrier 40 and the silicon device chip.

### DETAILED DESCRIPTION OF THE INVENTION

The present invention describes a novel and efficient method for testing known good die without requiring die shear according to which, in one aspect, specially designed reworkable and solvent-free conductive adhesive bumps are used for temporary interconnection between the chip carrier and the semiconductor device, and the chip carrier/device assembly is subjected to electrical test and burn-in to evaluate the device performance.

The present invention is particularly concerned with a method for temporary chip attachment to pre-screen silicon die prior to final assembly using specially designed reworkable conductive adhesive compositions having high electrical conductivity and reworkability after chip test and burn-in.

In another aspect of the invention there is disclosed a non-shear method to remove the chip from the carrier after the chip has gone through the test and burn-in using a rework solution that selectively softens/disrupts the conductive adhesive joint integrity and thereby allowing the die to be dislodged from the carrier by gently pulling or sliding it off the surface. The removed die is subsequently rinsed, preferably spray rinsed with a solvent, then DI water and with IPA thoroughly to remove any organic and/or conductive particulate if present on the chip or the substrate side.

The method described herein is applicable to ceramic chip carriers including high performance glass ceramic single chip modules (SCMs), dual-chip modules (DCMs), and multi-chip modules (MCMs) as well as to organic board as FR4 substrate for plastic packages with flip-chip bonding through contact pads directly onto printed circuit board. The method applies to flip-chips with standard Pb/Sn alloy C4s including eutectic Pb/Sn, and Pb-free solder bumps as Sn/Cu, SnAgCu and alternate Pb-free alloys. More particularly, this invention is concerned with conductive adhesives with improved functional properties in terms of electrical conductivity, thermal stability, compatibility with the interfacing metallurgy, process simplicity and at the same time having the special feature of reworkability such that the die can be removed from the TCA carrier by exposure to a suitable rework solution without the need to apply shear force to pull the die.

In case of the high performance glass ceramic chip carriers which have copper via metallurgy, the method according to this invention has the distinct advantage of providing a means to pre-test die that it does not depend on selective surface wetting by solder nor designing special test vehicles with multiple layer complex metallurgy schemes and thus provides a simpler alternative to the die commonly used shear method.

The new method according to this invention is based on the use of specially designed solvent-free conductive adhesive compositions in terms of the chemistry of the organic polymer matrix, particle size and % loading of the conductive metal filler, paste viscosity and rheology; thermal stability and electrical conductivity of the fully cured adhesive as well as its interface integrity under T/H and thermal cycling stress conditions. A highly desirable and novel feature of the conductive adhesives employed for the temporary interconnection with the chip C4 solder bumps according to the present invention is that the cured adhesive can be removed by exposure to a rework solution (non-shear method) and the die is separated from the TCA assembly without using shear method.

The method involves forming reworkable conductive adhesive bump arrays of desired dimension and spacing on a test vehicle or actual module substrate on top of pads in the C-4 cage by screen printing, syringe dispensing, or using autodispense tools. Then partially drying the adhesive patterns, placing and aligning the solder C4 array features (flip-chip) on die to be tested with the adhesive bumps on the substrate side, subjecting the assembly to cure conditions for the conductive adhesive with application of mild pressure on top to keep the assembly in alignment and pressed down during cure, and subjecting the assembly to standard test and burn-in process using a specified thermal interface cooling medium and /or heatsink on the back side of chip.

After the die has been evaluated, the assembly is exposed to a rework solution that selectively softens/disrupts the adhesive joint integrity allowing the die to be dislodged from the carrier by gently pulling or sliding it off the surface. The removed die is subsequently put through a series of rinse cycles with solvent, deionized water, and finally IPA and dried to remove any trapped moisture. In this rework process, the conductive adhesive bumps on the carrier C4 pads will also be removed and thus the carrier has to be repopulated with fresh bumps for the second time use.

In another embodiment of the present invention multiple use of the TCA carrier is provided whereby a first array of conductive adhesive bumps is formed using a non-reworkable conductive adhesive on the top of which is screen printed or dispensed a thin deposit of the reworkable conductive adhesive. The rest of the process for chip join, test and burn-in, and rework remain the same as in the first embodiment, but in this case only the top thin deposit will need to be redeposited since the bulk adhesive column array which is made up of non-reworkable conductive adhesive will remain intact in the chip removal process. It is preferred that after depositing the conductive adhesive bumps on the carrier side, the adhesive is dried at about 90° C. for 5-10 minutes before placing and aligning with the flip-chip C4 solder bumps in order to avoid the possibility of smear and loss the alignment that can occur with wet paste.

After assembling the chip and the TCA chip carrier, it is subjected to the cure step to fully cure the conductive adhesive joints with application of mild pressure on top to keep the assembly in alignment and pressed down during cure, and subjecting the assembly to standard test and burn-in process using a specified thermal interface cooling medium and /or heatsink on the back side of chip.

In another embodiment of the present invention, the conductive adhesive is applied on both the substrate contact pads and as a thin bonding coat on top of the chip C4 arrays or alternately the conductive adhesive can be used to replace solder bumps altogether by forming C4 pattern on the device chip interconnection metallurgy using screen printing or dot dispense tool. With the adhesive on both components, the joining will occur through adhesive-to-adhesive bond formation upon subjecting the assembled structure to the adhesive curing process.

Several conductive material paste compositions were considered and tested for ceramic TCA application which are based on epoxy matrix but none of the commercial formulations met the requirements for applicability to the design of glass ceramic TCA in particular. The commercially available conductive adhesives of conventional type are mostly Ag-filled thermoset or flexible epoxy matrix based paste compositions and have the major problem that once fully cured, these adhesives cannot be easily removed from the surface of electronic components. The conductive adhesive compositions found suitable for the purpose of this invention are the modified versions of the chemistry makeup described previously in U.S. Pat. Nos. 5,700,581 and 6,548,175. These are multi-component conductive paste formulations containing high level of metal flake and/or powder filler dispersed in a polymer matrix derived from a liquid epoxy precursor preferably having a siloxane linkage (—Si—O—Si—) and carrying an acyclic or cyclic chain segment, and utilize standard solid or liquid anhydride or an amine as cure additives.

The conductive adhesives that are found to be best suited for the application according to this invention to form well defined fine pitch dot patterns are of specially designed chemistry based on solvent-free low stress compliant hybrid epoxy polymer matrix with the epoxide precursor having a flexible chain linkage, preferably alkyl siloxane (—Si—(OSi—)ₙ — with a low stress low Tg polymeric/oligomeric additive and comprising high loading of fine particle size noble metal surface coated Ag or Cu filler.

The distinguishing features of the reformulated compositions according to this invention are the complement of properties desired for forming well defined uniform shape conductive bump pattern on the substrate side C4 cage bonding pads or on the top of the solder ball array on the chip side; show no resin bleed or spreading of conductive particles beyond the dot boundary; form low resistivity cured coating and exhibit TCR stability (thermal coefficient of resistance); good adhesion to all relevant surfaces which are typically Au surface pads on the substrate side; lead/tin alloy solder ball; under-solder ball metallurgy (BLM), or SnAgCu solder arrays on the chip side in the case of lead-free assembly; and adhere well to itself which is important when the adhesive is applied on both the substrate pads and as a thin bonding coat on top of the chip C4 arrays or as a conductive bump to replace solder bumps altogether. With the adhesive on both components, the joining will occur through adhesive-to-adhesive bond formation upon subjecting the assembled structure to the adhesive curing process.

As a variation of the process using reworkable conductive adhesive for TCA application, the C4 solder ball array on the chip circuit for flip-chip joining can be replaced entirely by the reworkable conductive adhesive bump array with similar footprint as the solder ball C4s. With the current focus on lead-free and environmentally friendly materials and processes in the various consumer product categories; strict regulations on the hazardous waste handling and disposal; and the increasing production cost of advanced electronic devices, this approach should limit/eliminate the need for using lead based alloys in electronic assembly processes.

The most preferred conductive adhesives for the temporary chip attachment to pre-test the silicon devices according to the present invention are formulated with noble metal surface coated metal fillers, specifically Pd-coated-Ag, Au-coated-Ag, Ag-coated-Cu, Ag flake or powder in combination with Au-coated-Ag, spherical Ag powder, carbon fibers, particularly carbon microfibers, and combination thereof. The particle size of the filler can be primarily monodisperse or polydisperse phase, shape and morphology, the filler that assures high packing density is preferred. The polymer matrix composition of this invention can allow dispersion of these fillers at levels up to 80-90 wt % in organic binder system to obtain conductive paste viscosity suitable for manual dispense, screen or stencil printing, or with an auto-dispense tooling.

The cured adhesives can be readily removed from the chip side and the TCA carrier side after separating the two components which can be done by exposing the carrier-chip assembly after test and burn-in to a rework solution such as a dilute solution of a quaternary ammonium fluoride in a non-polar aprotic solvent described previously (U.S. Pat. No. 6,652,665) followed by multiple rinse cycles using solvent, deionized water, IPA and dry.

During test and burn-in, a cooling medium is typically employed on the back side of the chip for heat dissipation and electrical considerations. Several candidate materials have been used and described in the prior art, for example, thermal greases can be spread as a thin layer between the back of the die, phase change materials (PCM) which are low melting waxes as paraffin wax, silicone based waxes which can be used as pre-formed tapes or melt dispensed across interfaces, or high thermal conductivity fluids.

In another aspect of this invention, as alternative to the above materials for heat dissipation during test and burn-in, the reworkable and compliant conductive adhesives can be used with advantage as a thin layer on the back side of the chip between the heatsink to serve as an effective interface layer. For this application, the adhesive can be applied as a thin layer on the heatsink or the back side of the chip and fully cured prior to assembly for test and burn-in. Since these adhesives are low modulus and compliant, necessary chip to heatsink contact is obtained when pressure is applied on the assembly. An important benefit of the reworkable conductive adhesive as interface layer in the TCA test and burn-in is that after multiple use, the heatsink can be cleaned with the rework method as described herein and reused for further operation. The adhesive on the back side of the chip if used in that mode will be automatically removed during the chip removal process.

FIG. 1 shows a representative ceramic TCA chip carrier substrate 10 having plurality of co-sintered metal vias with bonding pads 11 having Ni-P/immersion Au surface metallurgy deposited over the top of the vias, and having the conductive adhesive bumps 12 deposited on the top of the via bonding pads metallurgy. The single chip 20 having C4 solder ball array 21 for flip-chip bonding is the silicon device chip for pre-assembly performance test and burn-in to evaluate circuit continuity through flip-chip solder ball array connections with the conductive adhesive bumps on the substrate bonding pads.

FIG. 2 shows the assembled structure 30 after the flip-chip placement such that the C4 solder balls 21 are aligned with the conductive adhesive bumps 12 on the substrate bonding pads, and curing the adhesive using the necessary weight on the top of the chip to maintain alignment during cure. For test and burn-in, a cooling medium 31 as thermal interface adhesive is dispensed on the back side of chips for heat dissipation during burn-in and electrical test.

FIG. 3 shows the separated TCA carrier 10 and the silicon device chip 20 after the test has been completed and the chip removed from the assembled structure 30 by subjecting to the rework solution which allows the conductive adhesive bond to soften or partially dissolve the organic binder system of the adhesive which facilitates chip removal without applying shear force. After removing it from the carrier, the chip is thoroughly cleaned free of any organic or metallic residue and the cooling medium by a series of solvent and DI water rinse cycles followed by nitrogen dry and bake.

As shown in FIG. 3, the rework process for chip removal after test and burn-in also removes the conductive adhesive bumps on the top of the substrate bonding pads which requires fresh coat of the adhesive for multiple use of the TCA carrier. The substrate can be a typical single chip (SCM) or multi-chip ceramic chip (MCM) carrier for temporary chip attachment using conductive adhesive bumps to test one or multiple number of chips with one cycle for adhesive bumps application. In the case of a multi-chip carrier assembly, for example having a ceramic chip carrier with conductive adhesive bumps deposited onto the bonding pads in the C4 cage attached to a plurality of silicon chips through conductive adhesive-solder joints. Alternatively, the substrate can be organic composite based carrier as printed circuit board for flip-chip or direct chip attach (DLA). The chip size is not critical.

The following examples are representative of the relevant chemistry make up of the conductive adhesives found suitable for temporary chip attachment to obtain TCA carrier to test for known good die and application to glass ceramic, alumina ceramic, and organic packaging components.

The organic matrix binder system of the conductive adhesive compositions according to this invention is based on epoxy-low Tg compliant polymer additive and standard constituents for epoxy polymers which are, liquid epoxide precursor, conventional anhydride or amine curing agent, curing catalyst/cure accelerator system, along with other additives as antioxidants, corrosion inhibitors, surface wetting agents.

A large variety of the conventional commercially available conductive adhesive materials are based on diglycidyl ethers of bisphenol A and bisphenol F with Ag flake or powder as the conductive filler. For the purpose of this invention, the preferred liquid epoxide precursors are: bis(1,3-glycidoxy propyl)tetramethyl disiloxane; aliphatic diglycidyl ethers such as bis(1,4butane diol)diglycidyl ether and mixture thereof; bis(1,5 glycidoxy propyl)hexamethyl trisiloxane; 1,4-cyclohexane-dimethyl diglycidyl ether and related liquid cycloaliphatic diepoxides. The curing agents used are preferred to be saturated aliphatic anhydrides which may be liquid or low melting solids which is miscible with the liquid epoxy precursor and forms a stable homogeneous mixture at room temperature or by heating up to 70-80° C. Representative candidates for suitable anhydrides include: hexahydrophthalic anhydride (HHPA), hexahydro-4-methyl phthalic anhydride (MeHHPA), dodecynylsuccinic anhydride (DDSA); octenyl succinic anhydride; hexadecenyl succinic anhydride; cis-4-cyclohexane-1,2dicarboxylic anhydride or cis-1,2,3,6-tetrahydrophthalic anhydride (THPA); methyl-5-norbornene-2,3-dicarboxylic anhydride; maleic anhydride, and mixtures thereof.

The polymeric additive used in these epoxides can be an acrylate polymer such as polyacrylate such as poly(n-butylacrylate or n-butylmethacrylate) of low molecular weight preferably having intrinsic viscosity <0.5; poly(n-fluorobutyl methacrylate), low molecular weight poly(methyl methacrylate) preferably having molecular weight <10,000, and mixtures thereof. These are generally described previously in U.S. Pat. No. 6,548,175. As an alternative to the polyacrylate derived polymeric additives, it is found that a terminally functionalized low glass transition temperature (Tg) oligomer, poly(acrylonitrile-co-butadiene-co-acrylic acid) dicarboxy terminated glycidyl methacrylate diester (ABA-glycidyl methacrylate diester), having average Mn 3,600, 15-18% acrylonitrile segment, and viscosity 1,600 Poise, form a highly compatible blend with the siloxane epoxide precursor monomer and the cured adhesive derived therefrom has improved adhesive properties and higher thermal stability when used with anhydride curing system. Another similar functionalized oligomeric additive, for example, the amine terminated poly(acrylonitrile-co-butadiene) with terminal secondary amine functional groups, also having 15-18 wt % acrylonitrile, and viscosity 2,000 Poise can be used with advantage in amine curing conductive adhesive compositions. Preferred catalysts according to this invention are essentially all conventional type as is commonly known and are also described previously in U.S. Pat. No. 6,548,175.

Preferred metal fillers include Pd-coated Ag, Au-coated Ag, Ag, Ag-coated Cu, spherical Ag powder, carbon fibers, particularly carbon microfibers, and combination thereof. The particle size of the filler can be primarily monodisperse or polydisperse phase with varying particle distribution, shape and morphology, the fillers that have average particle size less than 10 um when in the form of flakes while with the powder/flake bimodal distribution, the median size distribution is preferred to be less than 5 um and have narrow particle size distribution that assures high packing density. The polymer matrix composition of this invention can allow dispersion of these fillers as high as 80-90% (wt %) to obtain conductive paste viscosity suitable for manual dispense, screen or stencil printing, or with an autodispense tooling. Typical viscosity of freshly formulated conductive adhesives for thermal interface application can be in the range 20,000 to 60,000 Pa/S.

In a representative example of preparing the conductive adhesive paste formulation, 10% to about 30% (wt %) of the polymerictoligomeric additive is added to the liquid epoxide and the mixture allowed to stir at room temperature or at elevated temperature till it forms a homogeneous blend. The anhydride curing additive is then added to the mixture with the preferred mole ratio of the anhydride curing agent to the epoxy equivalent ranging from 1:1 to 1:2. When using a mixture of two anhydrides, the relative ratio of the anhydrides can be in the range 1:2 to 2:1. The mixture is then stirred at about 50-70° C. for 30 min to completely dissolve the anhydride. In an alternate procedure, epoxy/anhydride mixture is formed first and then the polymeric/oligomeric additive is blended in with mechanical mixing till a clear mixture is formed without requiring solvent addition. A catalyst/accelerator system used in conjunction with anydride curing epoxy formulations is added which commonly includes a tertiary amine, typically, 2,4,6-tris(dimethyl- aminomethyl) phenol, benzyldimethyl amine (BDMA), 2,6-diaminopyridine along with a proton source, typically nonylphenol, ethylene glycol, resorcinol, and related materials. All the organic components are thoroughly mixed together and the catalyzed system either be used immediately for dispersing the metal filler to form conductive paste or it can be stored at −20 or −40° C. for later use. Conductive metal filler is then dispersed in the catalyzed organic matrix by adding in portions and constant mixing with a rotary mixer, the amount of metal filler added varies between 75-90 wt % depending on the filler type, to obtain paste viscosity suitable for screen printing or dot dispensing using dispense tool to obtain conductive bump array on the TCA contact metallurgy or on silicon chip C4 solder bumps or on the chip UBL (under bump metallurgy) when using these adhesives as replacement of the solder ball array. After a homogeneous paste consistency is obtained for a desired application, the paste is deairated to remove any trapped air and stored at a minimum of −40° C. when not in use.

Curing and characterization of representative conductive adhesives described here for TCA application was carried out by forming thin coatings on glass slides, ceramic substrate, silicon wafers, and by printing C4 array patterns on ceramic substrates and silicon wafers using metal mask, and subjecting printed dot pattern to thermal treatment at 90-100° C. for 30 minutes followed by 160-175° C. for 60-90 minutes, preferably in a N₂ purged oven. Curing behavior of the adhesives was evaluated by differential scanning calorimetry (DSC) which showed exothermic transition with peak temperature ranging from 150° C. to 175° C. for the anhydride cure adhesives, the heat generally observed was in the range 35 to 60 J/g depending on the adhesive chemistry. Thermal stability was tested by carrying out thermogravimetric analysis (TGA) from room temperature to 250° C. at 10°/min ramp rate and also by isothermal TGA at 180° C. for extended period of time. The relevant dynamic and isothermal TGA data for the most preferred materials for TCA application according to this invention are summarized in table 1.

For resistivity measurements, the adhesives pastes were dispensed onto glass slides to form strips having about 4 cm length, 1 cm width and 0.8 to 1.2 mil wet thickness which on curing gives about 1 mil coating thickness. Resistivity measurements were carried out with a 4-point probe and the data for specific materials is collected in table 1.

A typical test method for the use of these adhesives for temporary chip attachment to provide a non-shear method for die test prior to module assembly involves dispensing the conductive paste bumps onto the C4 cage bonding pads on a test vehicle or the actual product ceramic chip carrier by paste screening using the Mo mask to replicate the top layer design with the peripheral dense area and central non-dense area bonding pads in the multilayer ceramic substrate, subjecting to about 5-10 minutes drying at about 85-90° C. in a N₂ purged oven, allowing to cool to room temperature and placing the chip with alignment of the adhesive bumps on the substrate side with the C4 Pb/Sn solder (97% Pb/3% Sn) ball arrays as for flip-chip joining, placing mild pressure or clamping down without disrupting the adhesive contact interface, and curing the adhesive in a N₂ purged oven 100-110° C. for 40 min followed by 160-175° C. for 90 min, allowed to cool down to at least 80° C. The assembly is subsequently subjected to chip test and burn-in and the exposed to rework process that disrupts the adhesive joint and allows die removal by pulling or sliding off of the surface with mild force. Once the die is separated, it is subjected to thorough rinsing, preferably spray rinsing with the same solvent that is used for rework solution makeup followed by deionized water pressure spay, and finally IPA to remove all organic and metallic residue.

In order to evaluate the quality of the mask screened dots of the various conductive pastes, the desired patterns were screen printed on glass slides and on silicon wafers, and subjected to full cure for the predetermined length of time with the upper temperature of 160-175° C. SEM micrographs of the cured bumps showed very well defined printed pattern with no merging, resin bleed, or metal particles extending beyond the dot boundary. All dots were essentially of the same dimension within experimental error. In a representative example of the dot screened pattern, the cured pattern array measured 29-33 um thickness, 100-110 um width, and 84-88 um spacing on silicon wafers.

TABLE 1

| | Epoxide^{a}/ | | | | | | |
|---|---|---|---|---|---|---|---|
| | Anhydride | | | TGA | TGA | DSC | |
| | Curing | Polymer | Conductive | Rt-250° | Isothermal | Exo peak | Resistivity |
| Example | Agent | additive^{c} | Metal Filler | % wt loss | /hr, 180° C. | /J/g. | (ohm-cm) |
| 1 | DDSA | n-BuMA | Au-coated Ag | 0.5 | 0.15 | 162-163° C. | 6.2.10⁻5 |
| | | polymer | flake/powder | | | 19-21 J/g | |
| 2 | DDSA | n-BuMA | Au-coated Ag | 0.55 | 0.16 | 162-163oC | 6.9. 10⁻⁵ |
| | | polymer | flake/powder | | | 21-22 J/g | |
| 3 | HHPA | ABGMA | Au-coated Ag | 0.5 | 0.18 | 156-158° C. | 8.3.10⁻⁵ |
| | | Polymer | flake/powder | | | 44-46 J/g | |
| 4 | HHPA | n-BuMA | Ag flake | 0.9 | 0.34 | 160-161° C. | 6.1.10⁻⁵ |
| | | polymer | SF9AL | | | 41-43 J/g | |
| 5 | MeHHPA | n-BuMA | Au-coated Ag | 0.59 | 0.2 | 158-160° C. | 4.9.10⁻⁵ |
| | +HHPA | polymer | flake/powder | | | 45-45 J/g | |
| 6 | MeHHPA | n-BuMA | Au-coated Ag | 1.0 | 0.25 | 162-163° C. | 6.7.10⁻⁵ |
| | +HHPA | polymer | flake/powder | | | 36-37 J/g | |

^{a}Epoxide = 1,3-bis(glycidoxypropyl) tetramethyldisioxane
^{b}HHPA = Hexahydrophthalic anhydride; DDSA = Dodecenyl succinic anhydride; MeHHPA = 4-Methyl Hexahydrophthalic anhydride;
^{c}nBuMA poly. = Poly(n-butyl methacrylate), intrinsic viscosity about 0.5, avg Mw, 320K, PMMA = Poly (methyl methacrylate), avg Mw 15,000
ABGMA polymer = Poly(acrylonitrile-co-butadiene-co-acrylic acid, dicarboxy terminated glycidyl methacrylate diester (ABA-glycidyl methacrylate diester).

The rework method comprises the steps of:

(a) providing a first stripping solution for the conductive adhesive bonding the silicon device C4s to the TCA carrier bonding pads, which comprises tetramethylammonium fluoride (TMAF) or a tetrabutylammonium fluoride (TBAF), or a mixture thereof dissolved in a first essentially water insoluble non-hydroxylic aprotic solvent, for example, propylene glycol methyl ether acetate (PGMEA), tetrahydrofuran (THF), acetonitrile (CH₃CN), toluene.

(b) submerging the electronic components assembly carrying the cured conductive adhesive joint in the first cleaning solution heated at 40 to 70° C., preferably 45 to 60° C. and allowing the components to be subjected to the cleaning action by the solution with stirring or agitation for a first predetermined period of time between about 10 to about 90 minutes, depending on the extent of polymer residue and the component surface topography;

(c) removing the assembly components from the first cleaning solution;

(d) transporting and submerging the composition in the first solvent rinse bath which comprises a hydrophobic non-hydroxylic solvent, preferably the same solvent as used for the first cleaning solution, and subjecting the components to the solvent rinse, for example, immersion rinse at room temperature to 70° C. with agitation, for a second predetermined period of time between about 5 to about 15 minutes, to replace the cleaning solution on the component surface with the solvent;

(e) removing the components from the first solvent rinse bath;

(f) transporting and submersing the components to the second solvent rinse bath which comprises a hydrophilic essentially water soluble solvent, and subjecting the components or parts to the second solvent rinse at room temperature to about 60° C. with agitation such as stirring or immersion spray for about 5 to 10 minutes;

(g) removing the components from the second solvent rinse bath;

(h) transporting the components to an aqueous rinse bath and applying a water rinse, preferably deionized water rinse, for example, spray or immersion spray rinse, at room temperature to about 50° C. for 2 to 10 minutes;

(i) subjecting the components to another brief rinsing step with IPA (isopropanol) to replace water on the component surface with IPA to accelerate drying;

(j) drying the components by blowing dry N₂ or air on the surfaces and then heating the assembly components at about 90° C. to about 120° C for 30 minutes to about one hour, preferably under vacuum to remove adsorbed moisture from the components.

In an alternative solvent rinse process, the assembly components or parts after the first solvent rinse in non-hydroxylic aprotic solvent such as PMA, are transported to a second solvent bath also containing a hydrophobic non-hydroxylic solvent, preferably the same solvent as used for the first cleaning solution and the first rinse solvent such as PMA, and subjecting the parts to the second solvent rinse similar to the first solvent rinse. After the second solvent rinse, the assembly components are transported to a bath containing IPA where the parts are subjected to a spray rinse or immersion rinse with IPA to replace the PMA solvent with IPA, and then dried by blowing dry N₂ or air on the surface followed by heating the component parts at about 90° C. to about 120° C. for 30 minutes to one hour, preferably under vacuum.

The preferred quaternary ammonium fluoride (QAF) compound in the first cleaning solution is tetrabutylammonium fluoride (TBAF) which is present at a concentration of about 0.2 to 5 weight %, preferably 0.5 to 1% based on the formula (C₄H₉)₄N⁺F⁻, or 0.6 to 1.5% (weight %) as the trihydrate (TBAF.3H₂O) in hydrophobic aprotic solvent, preferably propylene glycol methyl ether acetate (PGMEA).

The first solvent rinse bath comprising a non-hydroxylic aprotic solvent which is preferably the same solvent as in the first cleaning solution solvent in the category of propylene glycol alkyl ether alkoate selected from the group consisting of propylene glycol methyl ether acetate (PGMEA), propylene glycol ethyl ether acetate (PGEEA, bp. 158° C.), propylene glycol methyl ether propionate (methotate), di(proylene glycol)methyl ether acetate. (DPMA, bp. 200°), ethoxy ethyl propionate (EEP).

The second rinse solvent is a hydrophilic essentially water soluble solvent represented by propylene glycol alkyl ethers selected from the group consisting of di(propylene glycol)methyl ether (DPM, fp 75° C.), tri(propylene glycol)monomethyl ether (TPM, fp 96° C.), tri(propylene glycol) n-propyl ether, or a mixture thereof, used at a temperature from about room temperature to about 60° C.

In the alternative solvent rinse process, the parts after the first solvent rinse in PMA or related non-hydroxylic aprotic solvent are again subjected to the same solvent rinse, preferably PMA in a second solvent bath followed by spray or immersion rinse in EPA, and dried by blowing dry N₂ or air on the surfaces followed by heating the component parts at about 90° C. to about 120° C. for 30 minutes to one hour, preferably under vacuum.

### Preparation of the Representative Adhesives Compositions is Illustrated by he Following Examples. Relevant Chemistry and the Characterization Data are Shown in Table 1

### EXAMPLE 1

Dodecenylsuccinic anhydride (DDSA), 2.6 g was added to a solution of about 2.8 g of 1,3-bis(glycidoxy-propyl)tetramethyldisiloxane and 0.6 g of poly(n-butyl methacrylate) prepared by first dissolving the polymer in the liquid siloxane epoxide, and heating at 50-60° C. with stirring till a clear viscous solution was formed, then adding the anhydride and continued stirring to blend in the anhydride. The viscous mixture thus obtained was allowed to cool to room temperature and then 0.02 g of benzyldimethyl amine (BDMA), 0.03 g of 2,4,6-tris(dimethylaminomethyl) phenol (DMP-30), and 0.03 g nonylphenol were added and well mixed to form a clear homogeneous solution. About 27.5 g of Au-coated silver flake (90% Ag/10% Au surface coated,wt % ratio) as metal filler was dispersed in the catalyzed mixture with slow addition and continued mixing to form a conductive adhesive paste having about 82 wt % filler. The paste stored at −40° C. when not in use. Relevant characterization data for the cured adhesive are shown in Table 1

### EXAMPLE 2

A mixture of Dodecenylsuccinic anhydride (DDSA), 2.6 g, 1,3-bis(glycidoxy-propyl)tetramethyldisiloxane, 2.8 g, and poly(n-butyl methacrylate),0.6 g, prepared according to the method provided in Example 1. To this mixture at room temperature was added 0.025 g of nonylphenol, 0.025 g of ethylene glycol and 0.04 g benzyldimethyl amine and well mixed till a homogeneous mixture was formed. To about 5.5 g of this final catalyzed mixture was blended in 25.5 g Au-coated Ag (90% Ag/10% Au, wt %) filler to form a conductive adhesive paste having about 82.2% (wt %) filler loading. Measurement of resistivity and other relevant characterization data are summarized in Table 1.

### EXAMPLE 3

To a soluble mixture of 1.55 g of a 3-bis(glycidoxypropyl)tetramethyl disiloxane, 1.1 g hexahydrophthalic anhydride (HHPA), and 0.38 g poly(acrylonitrile-co-butadiene-co-acrylic acid, dicarboxy terminated glycidyl methacrylate diester (ABGMA oligomer) was added 0.03 g nonylphenol and 0.03 g of the tertiary amine 2,4,6-tris(dimethylamino-methyl)phenol (DMP-30) and thoroughly mixed to form a clear homogeneous solution. About 12.5 g of Au-coated silver flake were blended in this catalyzed mixture to form screenable conductive adhesive paste having about 80 . . . 5 wt % of the conductive filler. Relevant characterization data are given in Table 1.

### EXAMPLE 4

To a soluble mixture of 2.3 g of 3-bis(glycidoxypropyl)tetramethyl disiloxane, 1.4 g hexahydrophthalic anhydride (HHPA), and 0.4 g poly(n-butylmethacrylate) was added 0.03 g nonylphenol and 0.03 g of the tertiary amine 2,4,6-tris(dimethylamino-methyl)phenol (DMP-30) and thoroughly mixed to form a clear homogeneous solution. About 16.2 g of silver flake (SF9AL) were blended in this catalyzed mixture to form screenable conductive adhesive paste having about 79.8 wt % of the conductive filler. Relevant characterization data are given in Table 1.

### EXAMPLE 5

A mixture of 3.57 g of a 3-bis(glycidoxypropyl)tetramethyl disiloxane and 0.63 g of poly(n-butyl-methacrylate) was heated with stirring till a clear solution was formed and then 1.2 g 4-methyl hexahydrophthalic anhydride, 1.30 g hexahydrophthalic anhydride were added and the mixture allowed to stir for about 30 min till all solids dissolved. To about 3.2 g of this mixture was added 0.025 g nonylphenol, 0.02 g ethylene glycol and 0.025 g DMP-30 and the contents thoroughly mixed till it formed a clear homogeneous solution. About 15.3 g of Ag/Au filler (90% Ag/10% Au wt % ratio) was blended in this catalyzed mixture according to general method described above to form a conductive adhesive paste having about 82.4 wt % Ag/Au filler

### EXAMPLE 6

A soluble mixture of 4.0 g of 3-bis(glycidoxypropyl) tetramethyl disiloxane, and 0.80 g of poly(n-butylmethacrylate) was prepared by heating at about 60-70° C. followed by the addition of 1.2 g MeHHPA and 1.3 g HHPA and continued stirring to dissolve the anhydride. The mixture thus obtained was catalyzed by the addition of 0.03 g nonylphenol and 0.025 g of 2,4,6-tris(dimethylaminomethyl) phenol (DMP-30), and in addition 0.15 g bis-methacryloxypropyl tetramethyldisiloxane was added and thoroughly mixed to form a clear homogeneous solution. About 30.5 g of Ag/Au filler (90% Ag/10% Au wt % ratio) was blended in this catalyzed mixture according to general method described above to form a conductive adhesive paste having about 80.2 wt % Ag/Au filler.

It will be apparent to those skilled in the art having regard to this invention that other modifications of this invention beyond those embodiments specifically described here may be made without departing from the spirit of the invention. Accordingly, such modifications are considered within the scope of the invention as limited solely by the appended claims.

What is claimed is:

1. A method for temporary chip attach comprising the steps of:
applying reworkable conductive adhesive bumps of desired dimension and spacing on the electrical contact pads of a TCA chip carrier substrate;
partially drying said adhesive bumps;
placing and aligning the electrical contacts on a semiconductor chip to be tested with said adhesive bumps on said substrate contact pads to create a conductive interface;
applying a force to the semiconductor chip/substrate assembly to maintain alignment and pressure at said conductive interface;
curing said conductive interface between the semiconductor chip and the TCA chip carrier by subjecting the assembly to a cure step;
subjecting the assembly to a test and burn-in process using a thermal interface cooling medium and /or heatsink on the back side of said semiconductor chip.

2. The method of claim 1 where said reworkable conductive adhesive bumps are applied by screen printing.

3. The method of claim 1 where said reworkable conductive adhesive bumps are applied by syringe dispensing.

4. The method of claim 1 where said reworkable conductive adhesive bumps are applied using autodispense tools.

5. The method of claim 1 where said substrate contact pads are for metallurgical connection with the said conductive adhesive overlay on the said electrical contacts on the semiconductor device.

6. The method of claim 1 where said electrical contacts are a solder ball array for C4 flip-chip connection.

7. The method of claim 1 further comprising the step of using a thermal interface material and a heatsink on the back side of said chip during said test and burn-in.

8. The method of claim 1 further comprising the steps of exposing said assembly to a rework solution that selectively softens and disrupts said conductive interface; and
removing said semiconductor chip from said substrate.

9. The method of claim 8 further comprising the steps of subjecting said removed semiconductor chip to a rinse cycles with solvent;
subjecting said removed semiconductor chip to a rinse cycle with deionized water;
subjecting said removed semiconductor chip to a rinse cycle with IPA; and
drying said semiconductor chip thereby cleaning said chip of said adhesive bumps.

10. The method of claim 1 wherein said TCA chip carrier substrate is a alumina ceramic substrate.

11. The method of claim 1 wherein said TCA chip carrier substrate is a glass ceramic substrate.

12. The method of claim 1 wherein said TCA chip carrier substrate is an organic chip carrier substrate.

13. The method of claim 1 wherein said TCA chip carrier substrate is a multi-chip carrier substrate.

14. The method of claim 7 wherein said thermal interface material is selected from the group consisting of reworkable conductive adhesives.

15. The method of claim 14 where said reworkable conductive adhesive layer is bonded to a heatsink

16. The method of claim 14 where said conductive adhesive layer is bonded to the back of said semiconductor chip.

17. The method of claim 14 wherein said reworkable conductive adhesive thermal interface layer can be removed by a rework solution.

18. The method of claim 17 wherein said rework solution is comprised of quaternaryammoium fluoride dissolved in non-hydroxylic aprotic solvent.

19. The method of claim 1 where said partial drying of the adhesive bumps involves heating at a temperature of approximately 90° C. for approximately 5 to 10 minutes.

20. The method of claim 1 where said curing of the conductive interface involves heating the assembly at about 160-175° C. for about 60-90 minutes in N₂ ambient.

21. The method of claim 1 further comprising the step of applying a thin bonding coat of reworkable conductive adhesive on said semiconductor chip electrical contacts.

22. A method for temporary chip attach providing multiple use of a TCA chip carrier comprising the steps of:
applying a first array of non-reworkable conductive adhesive bumps of desired dimension and spacing on the contact pads of a TCA substrates and curing said adhesive bumps;
applying a second array of reworkable conductive adhesive bumps on the top of said first cured array;
partially drying said second array of reworkable adhesive bumps;
placing and aligning the electrical contacts on a semiconductor chip to be tested with said adhesive bumps on said substrate to create a conductive interface;
applying a force to keep the semiconductor chip/substrate assembly in alignment and under pressure;
curing said conductive interface by subjecting the chip/substrate assembly to a cure step while maintaining said force during cure;
placing a heatsink with a bonded thermal interface material layer at the back of said semiconductor chip and subjecting the assembly to test and burn-in.

23. The method of claim 22 further comprising the steps of exposing said assembly to a rework solution that selectively softens and disrupts said second array of adhesive bumps; and
removing said semiconductor chip from said substrate.

24. The method of claim 23 further comprising the steps of subjecting said removed semiconductor chip to a rinse cycles with solvent;
subjecting said removed semiconductor chip to a rinse cycle with deionized water;
subjecting said removed semiconductor chip to a rinse cycle with IPA; and
drying said semiconductor chip thereby cleaning said chip of said second array of adhesive bumps.

25. A method for temporary chip attach comprising the steps of:
applying reworkable conductive adhesive bumps of desired dimension and spacing on the electrical contact pads of a semiconductor chip to be tested;
partially drying said adhesive bumps;
placing and aligning the electrical contacts on a TCA chip carrier substrate with said adhesive bumps on said chip contact pads to create a conductive interface;
applying a force to the semiconductor chip/substrate assembly to maintain alignment and pressure at said conductive interface;
curing said conductive interface between the semiconductor chip and the TCA chip carrier by subjecting the assembly to a cure step;
subjecting the assembly to a test and burn-in process using a thermal interface cooling medium and/or heatsink on the back side of said semiconductor chip.

26. The method of claim 25 wherein said conductive adhesive bumps are the semiconductor chip electrical contact pads.
